(19) United States
(12) Patent Application Publication
(10) Pub. No.: US 2022/0119952 A1
(43) Pub. Date: Apr. 21, 2022

(54) METHOD OF REDUCING DEFECTS IN A MULTI-LAYER PECVD TEOS OXIDE FILM

(71) Applicant: Applied Materials, Inc., Santa Clara, CA (US)

(72) Inventors: Rana Howlader, Sivasagar (IN); Hang Yu, San Jose, CA (US); Madhu Santosh Kumar Mutyala, Santa Clara, CA (US); Zheng John Ye, Santa Clara, CA (US); Abhigyan Keshri, Sunnyvale, CA (US); Sanjay Kamath, Fremont, CA (US); Daemian Raj Benjamin Raj, Fremont, CA (US); Deenesh Padhi, Sunnyvale, CA (US)

(73) Assignee: Applied Materials, Inc., Santa Clara, CA (US)

(21) Appl. No.: 17/074,961

(22) Filed: Oct. 20, 2020

(51) Int. Cl. C23C 16/50; C23C 16/40; H01L 21/02; C23C 16/458; C23C 16/455

(52) U.S. Cl. CPC C23C 16/50; C23C 16/401; H01L 21/02274; H01L 21/02164; C23C 16/45565; H01L 21/02216; C23C 16/4586

(57) ABSTRACT

Exemplary deposition methods may include electrostatically chucking a semiconductor substrate at a first voltage within a processing region of a semiconductor processing chamber. The methods may include performing a deposition process. The deposition process may include forming a plasma within the processing region of the semiconductor processing chamber. The methods may include halting formation of the plasma within the semiconductor processing chamber. The methods may include, simultaneously with the halting, increasing the first voltage of electrostatic chucking to a second voltage. The methods may include purging the processing region of the semiconductor processing chamber.

### TECHNICAL FIELD

The present technology relates to semiconductor processes and chamber components. More specifically, the present technology relates to modified components and deposition methods.

### BACKGROUND

Integrated circuits are made possible by processes which produce intricately patterned material layers on substrate surfaces. Producing patterned material on a substrate requires controlled methods of formation and removal of exposed material. As device sizes continue to shrink, particle contamination may be an increasing challenge. During deposition methods, material may deposit on chamber components, and this material may fall to the substrate subsequent deposition, which may affect device quality.

Thus, there is a need for improved systems and methods that can be used to produce high quality devices and structures. These and other needs are addressed by the present technology.

### SUMMARY

Exemplary deposition methods may include electrostatically chucking a semiconductor substrate at a first voltage within a processing region of a semiconductor processing chamber. The methods may include performing a deposition process. The deposition process may include forming a plasma within the processing region of the semiconductor processing chamber. The methods may include halting formation of the plasma within the semiconductor processing chamber. The methods may include, simultaneously with the halting, increasing the first voltage of electrostatic chucking to a second voltage. The methods may include purging the processing region of the semiconductor processing chamber.

In some embodiments, the first voltage may be +200 V or less. The second voltage may be +500 V or more. The semiconductor substrate may be electrostatically chucked to a substrate support. The semiconductor processing chamber may include a showerhead, and the deposition process may occur with the semiconductor substrate positioned at a first distance from the showerhead. The showerhead may be maintained at a first temperature during the deposition process. The method may further include repositioning the semiconductor substrate to a second distance from the showerhead when the first voltage is increased to the second voltage. The second distance may be greater than the first distance. The second distance may be more than 25% greater than the first distance. The deposition process may include depositing silicon oxide using tetraethyl orthosilicate.

Some embodiments of the present technology may encompass deposition methods. The methods may include forming a plasma of an oxygen-containing precursor within a processing region of a semiconductor processing chamber. The processing region may house a semiconductor substrate on a substrate support. The processing region may include a showerhead operating as a plasma-generating electrode within the semiconductor processing chamber. The methods may include, while maintaining the plasma of the oxygen-containing precursor, flowing a silicon-containing precursor into the processing region of the semiconductor processing chamber at a first flow rate. The methods may include ramping the first flow rate of the silicon-containing precursor over a period of time to a second flow rate greater than the first flow rate. The methods may include performing a deposition at the second flow rate of the silicon-containing precursor.

In some embodiments, the silicon-containing precursor may include tetraethyl orthosilicate. The period of time may be less than or about 10 seconds. Ramping the first flow rate may occur at a constant increase of from about 2 grams per second of the silicon-containing precursor to about 5 grams per second of the silicon-containing precursor. The deposition may be performed at a temperature of less than or about 500° C. The showerhead may be maintained at a temperature of less than or about 250° C. during the deposition. The processing region of the semiconductor processing chamber may be maintained free of the silicon-containing precursor while forming the plasma of the oxygen-containing precursor. The semiconductor substrate may include silicon, and forming the plasma of the oxygen-containing precursor may produce an oxygen-radicalized surface termination of the silicon of the semiconductor substrate.

Some embodiments of the present technology may encompass deposition methods. The methods may include electrostatically chucking a semiconductor substrate at a first positive voltage within a processing region of a semiconductor processing chamber. The methods may include performing a pre-treatment process. The pre-treatment process may include forming a plasma of an oxygen-containing precursor. The methods may include performing a deposition process. The deposition process may include forming a plasma within the processing region of the semiconductor processing chamber. The methods may include halting formation of the plasma within the semiconductor processing chamber. The methods may include, simultaneously with the halting, increasing the first positive voltage of electrostatic chucking to a second positive voltage. The methods may also include purging the processing region of the semiconductor processing chamber.

In some embodiments, the first positive voltage may be +900 V or less. The second positive voltage may be +500 V or less. The semiconductor substrate may be or include silicon. The pre-treatment process may produce an oxygen-radicalized surface termination of the silicon of the semiconductor substrate. The deposition process may produce a silicon oxide film overlying the semiconductor substrate. The silicon oxide film may have a thickness of or about 2.5 μm.

Such technology may provide numerous benefits over conventional systems and techniques. For example, the systems may limit or minimize deposition of falling particles subsequent deposition processes by repelling the particles during purging. Additionally, the operations of embodiments of the present technology may produce improved interfacial density of materials on a substrate, which may reduce formation of embedded defects and undercut during subsequent etching. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a deposition method according to some embodiments of the present technology.

FIGS. 3A-3C show schematic views of an exemplary processing chamber during operations in a deposition method according to some embodiments of the present technology.

FIG. 4 shows exemplary operations in a deposition method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During material deposition, such as of silicon oxide or other silicon-containing materials, plasma enhanced deposition may produce a local plasma between a showerhead or gas distributor, and a substrate support. As precursors are activated in the plasma, the deposition materials may form and deposit on the substrate. While this deposition is occurring, additional deposition may also occur in the processing chamber, such as dead zones within the chamber, where fluid flow may not be ideal. Additionally, the process of plasma generation may produce a sheath layer above the substrate, which may circulate and trap certain particles. When the plasma is turned off, materials attached to chamber components may flake off and fall to the substrate, and particles previously trapped in the plasma may also fall to the substrate. These additional particulates may produce defects on the deposited film, which may degrade or otherwise affect device quality.

Conventional technology has often accepted a certain amount of these residual particle effects. The present technology, however, may adjust processing sequences and utilize modified chamber components to prevent an amount of these defects. For example, the present technology may energize a positive electrostatic field to repulse net-positively charged defect particles from the substrate, allowing them to be pulled from the chamber.

Additionally, processing with certain silicon precursors, such as tetraethyl orthosilicate, may produce lower density films, such as silicon oxide films. While some processes, such as gap filling and low quality formation, may be improved, interfacial regions of the film and an underlying substrate may be characterized by porous and weaker film coverage. During subsequent etch processing, such as dry or wet etching, upon reaching the underlying substrate, the etchant may undercut the deposited film along the interfacial region between the deposited film and the substrate, which may lead to further peeling and film degradation during subsequent polishing or processing operations.

Conventional techniques have addressed this issue by often utilizing alternative precursors for deposition, or performing higher temperature depositions, which may increase film density. The present technology may overcome these limitations by priming a substrate surface and forming a higher quality interface. This may allow a low density film to be formed, which may be useful during intermediate process operations, while limiting or preventing undercut during subsequent etching. Additionally, by improving interfacial film quality, deposition may be performed at lower temperatures, which may increase deposition rate over conventional processes. After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

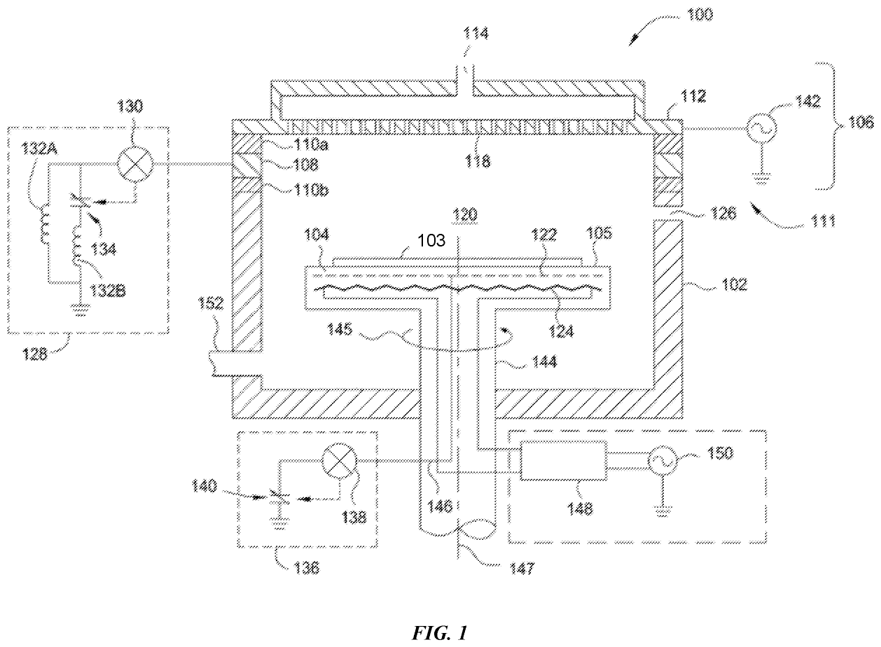

FIG. 1 shows a cross-sectional view of an exemplary processing chamber 100 according to some embodiments of the present technology. The figure may illustrate an overview of a system incorporating one or more aspects of the present technology, and/or which may perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

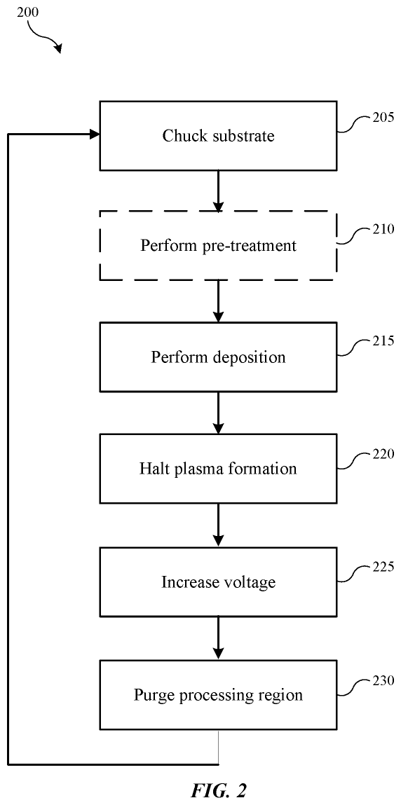

FIG. 2 shows exemplary operations in a deposition method 200 according to some embodiments of the present technology. The method may be performed in a variety of processing chambers, including processing chamber 100 described above. Additional aspects of processing chamber 100 will be described further below. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above. At operation 205, the substrate may be electrostatically chucked at a first voltage within the processing region of the semiconductor processing chamber. The pedestal may include an electrode disposed within the substrate support, such as the third electrode 124 of FIG. 1, for example. By applying a voltage to the electrode within the substrate support, an electric field may be applied to the substrate to clamp the substrate to the substrate support, and to compensate for and limit tensile effects on the substrate. The first voltage may be a positive voltage, such that the substrate support emanates an electrostatic field to repel positively charged particles from the surface of the substrate. While in a plasma, the relatively high mobility of electrons relative to ions may impart a net-negative surface charge to particles suspended in the plasma. For that reason, the first voltage may be applied as a first positive voltage, strong enough to clamp the substrate without also precipitating particles to the surface of the substrate, through a plasma sheath that may develop near the surface of the substrate.

Optionally, a pre-treatment process may be performed to activate the surface of the substrate at operation 210. In exemplary embodiments, the operations of method 200 may be performed in one or more cycles, as an approach to depositing a film, such as a silicon oxide film, on the substrate with a total thickness of at least 2.0 μm or more, of at least 3.0 μm or more, of at least 4.0 μm or more, of at least 5.0 μm or more, of at least 6.0 μm or more, of at least 7.0 μm or more, of at least 8.0 μm or more, of at least 9.0 μm or more, of at least 10.0 μm or more, of at least 11.0 μm or more, or more. The total thickness of the film may be composed of several overlying layers deposited in a corresponding number of process cycles. In some cases, a first layer, formed by a first cycle of method 200, may be affected by agglomeration of deposited film material onto particles that deposit on the surface of the substrate. For example, where particles fall or are otherwise deposited onto the film at one or more points during the process cycle, the decomposition products deposited on the surface of the substrate may be mobile on the surface and may form agglomerates with the particles. Subsequent deposition cycles to form additional overlying layers on the substrate may decorate the agglomerates, causing a defective film to form, rather than forming a uniform film of overlying layers. To limit agglomeration phenomena from affecting the uniformity of the film, and to further prevent the migration of chemisorbed or physisorbed species over the surface of the substrate, the pre-treatment process may be configured to activate the surface of the substrate.

Activating the surface of the substrate may include functionalization by oxygen radicals. For example, for a silicon substrate, pre-treatment may produce an oxygen-radicalized surface termination of the silicon of the semiconductor substrate. The oxygen radicals may be produced by a plasma generated in the semiconductor processing chamber from gaseous precursors including oxygen. The gaseous precursors, as described below, may be or include any gas that includes oxygen, but that does not decompose in the plasma to form reactive species that would also damage the substrate. Pre-treating the substrate by exposing the surface of the substrate to energetic plasma species may serve to increase the surface density of free radicals. Free radicals, in turn, may serve to increase the surface binding energy of plasma species on the surface of the substrate. The increased surface binding energy may reduce surface mobility of the plasma species and further reduce the extent of agglomeration effects. As an illustrative example, plasma species including silicon and oxygen, as may be employed to form silicon oxide films, may exhibit a stronger binding energy toward radicals than to a native silicon surface. In this way, producing an oxygen-radicalized surface termination of the substrate may bind silicon oxide species to a silicon substrate more strongly. In this way, pre-treatment may limit the mobility of plasma species on the surface during process operations undertaken at elevated temperatures, where otherwise mobility may be thermodynamically favored.

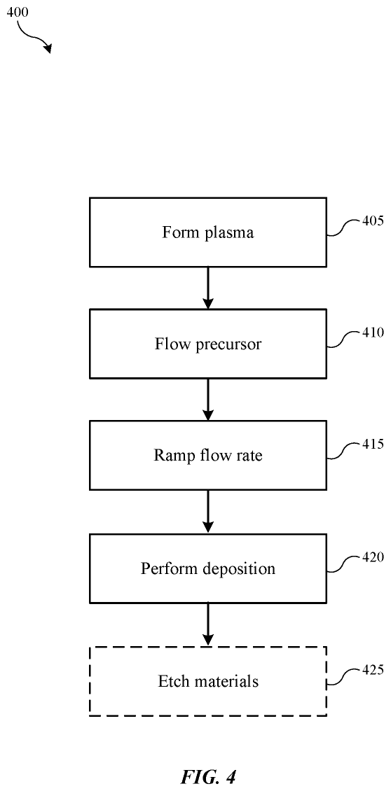

Subsequent pre-treatment, a deposition process may be performed at operation 215, in which a material is deposited on the substrate. In exemplary embodiments, the deposition process may involve forming a plasma within the processing region of the semiconductor processing chamber to perform a plasma-enhanced deposition process of any of a variety of materials, for example, although non-plasma deposition processes may also be performed. An exemplary process may involve depositing silicon oxide, and may include utilizing tetraethyl orthosilicate as a precursor. An exemplary deposition process that may be performed is discussed below with respect to FIG. 4, although this process is not intended to be limiting to the variety of deposition processes encompassed by the present technology, or the processes for which the present particle repulsion and purging operations may be performed. Subsequent the deposition, the process may be completed or stopped. This may include halting formation of the plasma within the semiconductor processing chamber at operation 220, and purging the chamber.

Conventional processing may de-chuck the substrate during plasma purging. For example, when the plasma is switched off, and a pumping or exhaust system is engaged to remove byproducts or residual precursor materials, many conventional systems may also switch off the voltage for electrostatic chucking. When the plasma is halted, particles that may have been suspended in the plasma sheath may then fall to the wafer and contaminate the surface. Additionally, when a purge operation is initiated, particles or deposition materials that have attached to a showerhead or chamber surfaces, may be detached. Although a portion of this material will be properly purged from the chamber, some of these particles may also be pulled from surfaces and fall to the substrate surface causing further contamination. As previously noted, many conventional technologies may simply accept this amount of contamination, and attempt to rectify the issue with additional polishing or post processing, for example.

The present technology may adjust the purging process, or the transition between processing and purging, relative to conventional technologies. For example, while many conventional operations switch off the electrostatic chucking, the present technology may maintain the voltage applied for chucking. As discussed above, embedded electrodes, such as third electrode 124 described previously, may create an electrostatic or clamping force that seats the wafer, and limits deflection. Put another way, the electrode creates an electrostatic field that radiates through the wafer, and in addition to the clamping force created, the field may provide an electrostatic repulsive force extending through the wafer. This force may be proportional to the magnitude of charge on the particle as well as on the substrate, due to the electrostatic chucking.

The voltage utilized for electrostatic chucking during the deposition process of operation 215 may be a first positive voltage that may be around +1000 V or less. The present technology may perform one or more modifications to the materials and methods performed, which may produce an adequate repulsive force to reduce or limit the contaminant particles reaching the substrate surface.

As will be explained further below, some embodiments of the present technology may implement multiple chucking voltages at different points during method 200, and a pedestal or substrate support utilized during method 200 may include embedded electrodes to apply the multiple chucking voltages. In this way, the present technology may utilize an applied chucking voltage during plasma purge operations, which may produce an electrostatic repulsive force against particles within a processing environment. As noted above, method 200 may include halting the plasma formation and/or deposition at operation 220. Unlike conventional technologies that may similarly halt the electrostatic chucking, the present technology may maintain the electrostatic chucking, and may increase the voltage in some embodiments. For example, at operation 225, and simultaneously with halting the plasma, or switching off the plasma, the method may include increasing the first voltage of electrostatic chucking to a second voltage greater than the first. This may produce an electric field providing a repulsive force to particles that may otherwise fall to the substrate. In some embodiments, the second voltage is a second positive voltage, such that particles exhibiting a net positive surface charge are repelled from the surface of the substrate. In contrast to the first voltage, the second voltage, being applied simultaneously or substantially simultaneously with halting the plasma, may have a magnitude exceeding that where precipitation of negatively charged plasma species may induce defects in the substrate or previously deposited film layers.

At operation 230, the processing region of the semiconductor processing chamber may be purged. This may involve maintaining or increasing operation of an exhaust or pumping system coupled with the processing chamber, as may occur typically in semiconductor processing. Because the electrostatic force repelling particles may be maintained during this purging operation, the contaminant particles may be removed prior to falling on the substrate.

As discussed above, electrostatic chucking may apply a positive voltage of about +1000 V or less in some embodiments. In some cases, depending on the configuration of the third electrode 124, the first voltage may be less than or about +900 V, than or about +800 V, than or about +700 V, than or about +600 V, than or about +500 V, than or about +400 V, than or about +300 V, than or about +200 V, or less.

When the voltage is transitioned from the first voltage to the second voltage, which may happen substantially instantaneously as an adjustment to the processing chamber, the voltage may be increased to greater than or about +300 V, and may be increased to greater than or about +400 V, greater than or about +500 V, greater than or about +600 V, greater than or about +700 V, greater than or about +800 V, greater than or about +900 V, or more. Although there may be correlation between increased voltage applied to the embedded electrode and the particle repulsion, increasing the voltage beyond a certain threshold, depending on substrate characteristics, may cause the substrate to bow, deform, or even break from the clamping force being applied. Accordingly, in some embodiments the second voltage may be maintained less than or about +1,100 V, less than or about +1,000 V, less than or about +900 V, less than or about +800 V, or less.

Processing operations may also be affected by the distance maintained between a substrate and a showerhead. As described with chamber 100, a pedestal or substrate support may be vertically translatable in some embodiments, and may position a substrate near the showerhead, such as gas distributor 112, during some deposition or other processing operations. The substrate may be maintained at this first distance from the showerhead throughout the deposition process. In some processing chambers encompassed by the present technology, exhaust flows may extend below the substrate support, such as with outlet 152 of FIG. 1. When the distance between the substrate and the showerhead is maintained sufficiently low, purge flow may not fully extend across the substrate. Accordingly, in some embodiments, method 200 may optionally include repositioning the substrate support during the purging operation.

For example, once plasma formation has been switched off or halted, and a purging operation may begin, the pedestal may reposition the substrate to a second distance from the showerhead, which may be a distance greater than the first distance. This may also occur when or while the first voltage is increased to the second voltage. By increasing the distance between the components, an exhaust flow may better draw across the showerhead, and may improve particle or contaminant removal. Accordingly, by increasing the distance, improved removal may be afforded. Hence, in some embodiments the second distance may be at least 25% greater than the first distance, and in some embodiments the second distance may be greater than or about 150% of the first distance, and may be greater than or about 200% of the first distance, greater than or about 250% of the first distance, greater than or about 300% of the first distance, greater than or about 350% of the first distance, greater than or about 400% of the first distance, greater than or about 450% of the first distance, greater than or about 500% of the first distance, greater than or about 550% of the first distance, or greater.

By performing an electrostatic repulsion according to embodiments of the present technology, particle contamination may be reduced relative to conventional technologies. For example, depending on the embedded electrode configuration and the voltage applied, experiments have illustrated that the particles of a threshold size were reduced from over one thousand particles to less than 20 particles. In some embodiments, applying a positive repulsion voltage may further reduce the particle contamination to less than or about 30% of a baseline amount of particles during conventional operations described previously, and may reduce particles to less than or about 25% of baseline particles, less than or about 20% of baseline particles, less than or about 15% of baseline particles, less than or about 14% of baseline particles, less than or about 13% of baseline particles, less than or about 12% of baseline particles, less than or about 11% of baseline particles, less than or about 10% of baseline particles, less than or about 9% of baseline particles, less than or about 8% of baseline particles, less than or about 7% of baseline particles, less than or about 6% of baseline particles, less than or about 5% of baseline particles, less than or about 4% of baseline particles, or less.

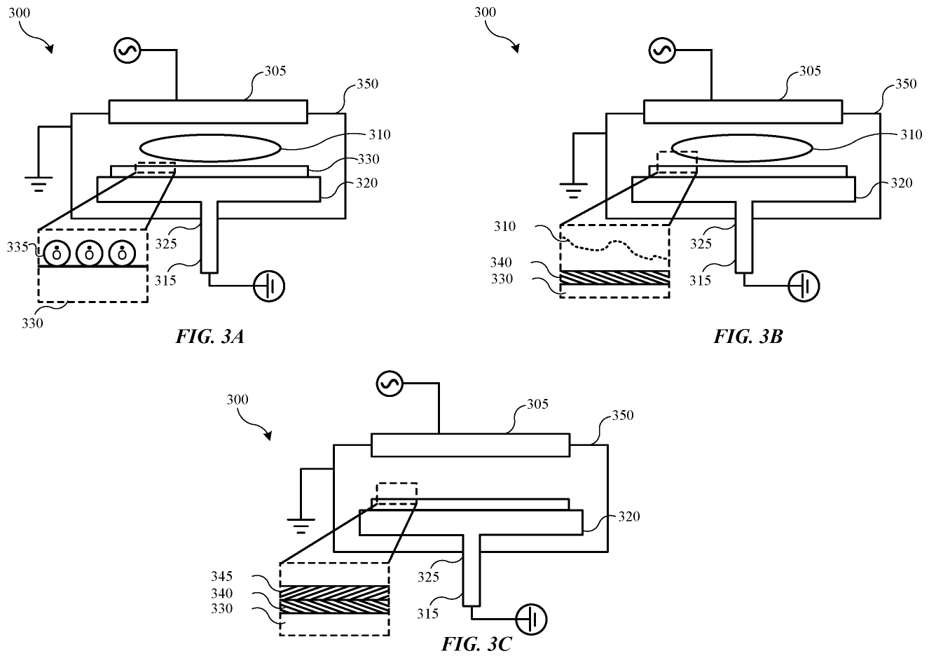

FIGS. 3A-3C show schematic views of an exemplary processing chamber during operations in a deposition method according to some embodiments of the present technology. FIGS. 3A-3C may illustrate further details relating to components in chamber 100, such as for pedestal 105 and gas distributor 112. System 300 is understood to include any feature or aspect of chamber 100 discussed previously in some embodiments. The system 300 may be used to perform semiconductor processing operations including pre-treatment, deposition, and purging operations as previously described, as well as other deposition, removal, and cleaning operations. System 300 may show a partial view of the chamber components being discussed and that may be incorporated in a semiconductor processing system, and may illustrate a view across a center of the pedestal and gas distributor, which may otherwise be of any size. Any aspect of system 300 may also be incorporated with other processing chambers or systems as will be readily understood by the skilled artisan.

System 300 may include a processing chamber including a showerhead 305, through which precursors may be delivered for processing, and which may be coupled with a power source for generating a plasma 310 within a processing region of the chamber. The showerhead 305 is shown at least partially internal to a processing chamber 350, and may be understood to be electrically isolated from the chamber 350, as described in reference to FIG. 1, such that the plasma 310 may be formed in a processing region of the chamber 350 between the showerhead 305 and a pedestal or substrate support 315. The pedestal 315 may extend through the base of the chamber 350. The substrate support may include a support platen 320, which may hold a semiconductor substrate 330 during pre-treatment, deposition, or purge processes, as described in more detail in reference to FIG. 1 and FIG. 2. The support platen 320 may be coupled with a shaft 325, which may extend through the base of the chamber 350. In addition to embedded electrodes described in connection with electrostatic chucking operations, the support platen 320 may also include a heater, that may facilitate processing operations including, but not limited to, deposition, etching, annealing, or desorption.

Through introduction of various precursor gases and control of plasma process conditions, the chamber may implement pre-treatment and deposition processes to form multilayer films onto wafers held on the support platen 320, for example, by electrostatic attraction, as well as purging processes of the chamber 350. In some plasma deposition processes, film material may also be deposited on exposed surfaces of the support platen 320, the showerhead 305, and exposed surfaces of the chamber 350. Residual material may have several impacts on process consistency and film uniformity. For example, film particles may detach from chamber surfaces and damage wafers. As another example, plasma properties may be affected by the change in electrical properties of the exposed surfaces, for example, by altering surface charge accumulation. To limit such effects, the residual material may be removed by purging the chamber 350 and cleaning the chamber 350 between process cycles.

As illustrated in FIG. 3A, deposition procedures may include a pre-treatment of the semiconductor substrate 330. During pretreatment, a positive voltage may be applied to embedded electrodes within the support platen 320, such that the substrate 330 is held to the support platen 320 through electrostatic chucking. The pre-treatment may include striking a plasma between the showerhead 305 and the pedestal 320 in the processing region, such that the substrate 330 is exposed to the plasma 310. The plasma, during the pre-treatment, may be formed of a mixture of inert and oxygen-containing gases, such as argon, helium, or nitrogen with oxygen containing species, such that the composition of the plasma includes a relatively high species density of oxygen radicals 335. In this way, the surface of the substrate 330, exposed to the plasma 310 and the energetic species of which it is composed, may develop an oxygen-radicalized surface termination of substrate 330, such as a high surface density of oxygen radicals 335. In FIG. 3A, the relative size of the oxygen radicals 335 are enlarged for illustrative purposes, and are not intended to indicate that the oxygen radicals are either macromolecules or monoatomic oxygen radicals. Instead, the oxygen radicals 335 may activate the surface of the substrate 330, either by binding to the surface directly or by radicalizing the atoms of surface of the substrate 330, producing the oxygen-radicalized surface termination.

As illustrated in FIG. 3B, the deposition process may form a film 340 on the substrate 330. As described in more detail in reference to FIG. 4, below, the film 340 may be produced through plasma decomposition of a silicon containing precursor, such as tetraethyl orthosilicate to produce energetic plasma species. The plasma 310 may form a vapor that may deposit onto the substrate surface 330, and may react while on the surface to form the film 340 through plasma-enhanced chemical vapor deposition (PECVD). As part of the deposition process, the pedestal 315 and the support platen 320 may be heated to a process temperature of above or about 400° C., of above or about 450° C., of above or about 500° C., of above or about 550° C., of above or about 600° C., or higher. While aspects of the support may be maintained at higher temperatures, in excess of 500° C. or higher in some cases, the showerhead 305 may be maintained at lower temperatures, such as below or about 300° C., below or about 250° C., below or about 200° C., below or about 150° C., below or about 100° C. or lower. The lower relative temperature may induce silicon oxide containing particles to form on the showerhead 305.

Particle deposition onto the showerhead 305 and the chamber 350 may pose numerous challenges for processing of semiconductor wafers, for example, due to detaching of particles from surfaces. Delamination or other stress-induced removal of the film 340 from the showerhead 305 may leave particles or fragments of the film 324 on the substrate 330. Particles, formed during deposition, may settle onto the substrate 330 and may limit the ability of structures to be formed by other semiconductor fabrication techniques where surface charge accumulation or line of sight govern the outcome of the techniques. This impact is in part because particles interfere with such processes, for example, by changing the interaction of a wafer with the plasma 310. In some embodiments, particles form embedded defects during deposition of multi-layer films having additional layers 345 overlying the film 340 as illustrated in FIG. 3C.

The film 340 may be limited to a practicable thickness before uniformity or structural issues limit the effectiveness of the film 340. For example, above a threshold thickness, internal stresses may accumulate and may lead to cracking or susceptibility to thermal deformation. To potentially avoid issues with film uniformity, the film 340 may have a thickness of less than or about 3.5 μm, less than or about 3.0 μm, less than or about 2.5 μm, less than or about 2.0 μm, less than or about 1.5 μm, less than or about 1.0 μm, or less. Following the deposition process, substantially instantaneous with quenching the plasma 310, a second positive voltage may be applied to the aspects of the support, greater than the first positive voltage during pre-treatment and deposition. The greater positive voltage may serve to repel those particles formed during the deposition process that have a net positive charge. For example, particles may develop a net positive charge by ionization during plasma synthesis that induces repulsion from the substrate 330 when it is a source of a positive electric field. In this way, applying a greater positive voltage, such as +500 V or more, may improve the repulsion and limit the number of particles that settle or otherwise attach to the substrate 330.

In some embodiments, the additional layers 345 may have substantially equal thickness to the film 340, depending on the parameters of the deposition process, and may be formed by repeating some or all of the process operations including, but not limited to, applying a chucking voltage, pre-treatment, deposition, and purging. As such, the total thickness of a multi-layer film including the film 340 and additional layers 345 may be greater than or about 4.0 μm, greater than or about 5.0 μm, greater than or about 6.0 μm, greater than or about 7.0 μm, greater than or about 8.0 μm, greater than or about 9.0 μm, greater than or about 10.0 μm, greater than or about 11.0 μm, greater than or about 12.0 μm, greater than or about 13.0 μm, greater than or about 14.0 μm, greater than or about 15.0 μm, or greater, and may be made up of multiple layers of film material deposited by a corresponding number of deposition process cycles.

As described above, deposition may be followed by purging of the chamber 350, such that the remaining plasma gas, unreacted precursors, plasma generated species, and residual particles entrained in the gas, may be removed. Purging may improve uniformity of pre-treatment and deposition by reducing residual plasma generated species and limiting particle growth in the chamber 350. Maintaining the second positive voltage during purging may permit positively charged particles to be removed from the chamber 350 by gas entrainment, without falling onto the substrate 330, which may reduce the number of particle defects in the film 340.

In addition to the processes as described above, the present technology may additionally provide improved silicon oxide and other material deposition. The deposition techniques described below may be combined with any of the repulsive force processes or equipment described previously. Tetraethyl orthosilicate (“TEOS”) may be characterized by a lower sticking coefficient than other silicon-containing precursors such as silane. While this effect may improve gap fill with reduced voids and overhang, this may similarly produce films with increased porosity and lower density. Although these characteristics may be sought in the bulk of the film being deposited, which may provide easier removal or etching, for example, increased porosity at an interface region may cause other challenges. For example, subsequent deposition, etching processes may be performed. When these etches reach the substrate, an undercut may occur to the film at the interfacial region. This may cause film peeling or chipping, which may be furthered with polishing operations.

Although densifying operations, such as anneals may improve this density, the anneal may densify the bulk of the film as well, which may remove the lower density sought, and may increase tensile stress through the film. This increased stress may also cause film peeling or other effects. Consequently, many conventional operations perform these depositions at relatively high temperatures, such as greater than or about 400° C., or greater than or about 500° C., which increases density throughout the film, but may be less than from an anneal. Because TEOS may deposit with more of a condensation-style effect, increased temperatures may also reduce the deposition rate.

The present technology may also improve low temperature deposition of oxide films deposited with TEOS by improving interfacial density of the film, while maintaining a porous, low density structure in the bulk, and increasing deposition rate over conventional techniques. The process may include ramping a rate of TEOS introduction into the processing chamber after radicalizing an interfacial surface of the substrate. This may improve bonding and lower porosity of the interfacial layer, prior to producing the lower density bulk region.

FIG. 4 shows exemplary operations in a method 400 of deposition according to some embodiments of the present technology. The method may be performed in one or more chambers, including any of the chambers previously described, and which may include any previously noted components, or utilize any methodology previously discussed subsequent processing. Method 400 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. For example, and as described previously, operations may be performed prior to delivering a substrate into a processing chamber, such as processing chamber 100 described above, in which method 400 may be performed with or without some or all aspects of method 200 previously described.

Method 400 may include forming a plasma of an oxygen-containing precursor within a processing region of a semiconductor processing chamber at operation 405. The processing region may house a substrate, such as on a substrate support, and on which the deposition process may be performed. Any number of oxygen-containing precursors may be utilized including diatomic oxygen, ozone, nitrogen-containing precursors that incorporate oxygen, water, alcohol, or other materials. During the plasma formation initially, the processing region may be maintained substantially or completely free of a silicon-containing precursor, such as TEOS or any other silicon-containing precursor. Any number of inert or carrier gases may be delivered with the oxygen, including, for example, helium, argon, nitrogen, or other materials.

Subsequent a first period of time, and while the plasma of the oxygen-containing precursor is maintained, a silicon-containing precursor may be flowed into the processing region of the semiconductor processing chamber at operation 410. The silicon-containing precursor may be delivered at a first flow rate that may be below a target flow rate for depositing a lower density silicon-and-oxygen-containing material. The flow rate of the silicon-containing precursor may be ramped over a second period of time at operation 415. The flow rate may be ramped at a constant rate over the second period of time, or may be ramped at a scaling rate, either decreasing or increasing, during the second period of time until the silicon-containing precursor may reach the target flow rate. The deposition may then proceed at the target flow rate to produce a desired film thickness at operation 420. By performing processes according to method 400, during subsequent etching operations, such as during a wet or dry etch in optional operation 425, undercut etching at the film interface with an underlying structure may be minimized or prevented.

As noted above, the silicon-containing precursor may be TEOS in some embodiments, although other silicon-containing precursors are similarly encompassed by the present technology. The first period of time and the second period of time may be variable based on the substrate geometry and characteristics, as well as the target flow rate and initial flow rate of the precursor. In some embodiments either or both time periods may be less than or about 1 minute, and may be less than or about 30 seconds, less than or about 20 seconds, less than or about 15 seconds, less than or about 10 seconds, less than or about 9 seconds, less than or about 8 seconds, less than or about 7 seconds, less than or about 6 seconds, less than or about 5 seconds, less than or about 4 seconds, less than or about 3 seconds, less than or about 2 seconds, less than or about 1 second, or less.

In some embodiments the first flow rate may be less than or about 50% of the target flow rate of the silicon-containing precursor, and may be less than or about 40% of the target flow rate, less than or about 30% of the target flow rate, less than or about 20% of the target flow rate, less than or about 10% of the target flow rate, or less. By utilizing a lower flow rate, less silicon material may be formed at the initial deposition. This may afford adequate time for byproducts to escape the film, which may reduce porosity and increase the film density.

By utilizing the oxygen plasma initially, such as for example on a silicon or silicon-containing substrate, although the process may be similarly performed on any other material, the oxygen may radicalize the surface forming an oxygen-radicalized surface termination, as described above in the context of operation 210 of method 200. Accordingly, this radicalized interface region may enhance reaction with the radical TEOS molecules when delivered, which may improve deposition at this surface. This may increase the density of the film prior to the increased deposition of a lower density film.

The ramping operation may be performed at a flow rate configured to slowly or quickly reach the target flow rate in some embodiments. For example, in some embodiments the flow rate may be increased at a rate of greater than or about 1 gram per second, and may be increased at a rate of greater than or about 2 grams per second, greater than or about 3 grams per second, greater than or about 4 grams per second, greater than or about 5 grams per second, greater than or about 6 grams per second, greater than or about 7 grams per second, greater than or about 8 grams per second, greater than or about 9 grams per second, greater than or about 10 grams per second, or more. Additionally, the flow rate may be increased within a range of from about 2 grams per second of the silicon-containing precursor to about 5 grams per second of the silicon-containing precursor. The flow rate ramping may also change over the ramping period to either go faster or slower over the ramping time. When the flow rate is ramped more slowly than this range, film deposition may not progress as uniformly, and extended exposure to plasma may impact the film. To improve uniformity of the delivery, a carrier gas as previously described may be provided at a flow rate of greater than or about 1 slm, and which may be greater than or about 2 slm, greater than or about 3 slm, greater than or about 4 slm, greater than or about 5 slm, greater than or about 6 slm, or greater.

When the flow rate is ramped more quickly than this range, deposition may occur more quickly, which may trap more byproducts, and may lead to increased porosity and lower density, as well as undercut of the film during etching. Accordingly, the flow rate may be increased at a measured rate to maintain a balance between film formation, and quality at the interface. The interfacial region may be characterized by a thickness of less than or about 10 nm prior to shifting to a lower density material, and in some embodiments the thickness of the higher density interfacial region may be less than or about 9 nm, less than or about 8 nm, less than or about 7 nm, less than or about 6 nm, less than or about 5 nm, less than or about 4 nm, less than or about 3 nm, less than or about 2 nm, less than or about 1 nm, or less.

By providing an increased density film at the interface, lower temperature deposition may be performed, while maintaining a quality interface during subsequent operations, and which may limit or prevent undercut during etching. Consequently, the present technology may allow deposition to be performed at a temperature of less than or about 500° C., and which may be performed at a temperature of less than or about 490° C., less than or about 480° C., less than or about 470° C., less than or about 460° C., less than or about 450° C., less than or about 440° C., less than or about 430° C., less than or about 420° C., less than or about 410° C., less than or about 400° C., less than or about 390° C., less than or about 380° C., less than or about 370° C., less than or about 360° C., less than or about 350° C., less than or about 340° C., less than or about 330° C., less than or about 320° C., less than or about 310° C., less than or about 300° C., less than or about 290° C., or less.

By utilizing methods and components according to embodiments of the present technology, material deposition or formation may be improved. By providing fewer embedded defects in a film, multilayer films may exhibit improved uniformity and structural integrity. These improvements may include reduced particle defect density in a film on a substrate, and may limit downstream damage to the film. Additionally, by performing particle repulsion operations as previously described, film contamination may be reduced over conventional techniques, which may increase device quality and yield.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A deposition method comprising:
electrostatically chucking a semiconductor substrate at a first voltage within a processing region of a semiconductor processing chamber;
performing a deposition process, wherein the deposition process comprises forming a plasma within the processing region of the semiconductor processing chamber;
halting formation of the plasma within the semiconductor processing chamber;
simultaneously with the halting, increasing the first voltage of electrostatic chucking to a second voltage; and
purging the processing region of the semiconductor processing chamber.

2. The deposition method of claim 1, wherein the first voltage is +200 V or less.

3. The deposition method of claim 1, wherein the second voltage is +500 V or more.

4. The deposition method of claim 1, wherein the semiconductor substrate is electrostatically chucked to a substrate support, wherein the semiconductor processing chamber comprises a showerhead, and wherein the deposition process occurs with the semiconductor substrate positioned at a first distance from the showerhead.

5. The deposition method of claim 4, wherein the showerhead is maintained at a first temperature during the deposition process.

6. The deposition method of claim 4, further comprising:
repositioning the semiconductor substrate to a second distance from the showerhead when the first voltage is increased to the second voltage, wherein the second distance is greater than the first distance.

7. The deposition method of claim 6, wherein the second distance is more than 25% greater than the first distance.

8. The deposition method of claim 1, wherein the deposition process comprises depositing silicon oxide using tetraethyl orthosilicate.

9. A deposition method comprising:
forming a plasma of an oxygen-containing precursor within a processing region of a semiconductor processing chamber, wherein the processing region houses a semiconductor substrate on a substrate support and comprises a showerhead operating as a plasma-generating electrode within the semiconductor processing chamber;
while maintaining the plasma of the oxygen-containing precursor, flowing a silicon-containing precursor into the processing region of the semiconductor processing chamber at a first flow rate;
ramping the first flow rate of the silicon-containing precursor over a period of time to a second flow rate greater than the first flow rate;
performing a deposition at the second flow rate of the silicon-containing precursor.

10. The deposition method of claim 9, wherein the silicon-containing precursor comprises tetraethyl orthosilicate.

11. The deposition method of claim 9, wherein the period of time is less than or about 10 seconds.

12. The deposition method of claim 9, wherein ramping the first flow rate occurs at a constant increase of from about 2 grams per second of the silicon-containing precursor to about 5 grams per second of the silicon-containing precursor.

13. The deposition method of claim 9, wherein the deposition is performed at a temperature of less than or about 500° C. of the semiconductor substrate, and wherein the showerhead is maintained at a temperature of less than or about 250° C. during the deposition.

14. The deposition method of claim 9, wherein the processing region of the semiconductor processing chamber is maintained free of the silicon-containing precursor while forming the plasma of the oxygen-containing precursor.

15. The deposition method of claim 9, wherein the semiconductor substrate comprises silicon, and wherein forming the plasma of the oxygen-containing precursor produces an oxygen-radicalized surface termination of the silicon of the semiconductor substrate.

16. A deposition method comprising:
electrostatically chucking a semiconductor substrate at a first positive voltage within a processing region of a semiconductor processing chamber;
performing a pre-treatment process, wherein the pre-treatment process comprises forming a plasma of an oxygen-containing precursor;
performing a deposition process, wherein the deposition process comprises forming a plasma within the processing region of the semiconductor processing chamber;
halting formation of the plasma within the semiconductor processing chamber;
simultaneously with the halting, increasing the first positive voltage of electrostatic chucking to a second positive voltage; and
purging the processing region of the semiconductor processing chamber.

17. The deposition method of claim 16, wherein the first positive voltage is +900 V or less.

18. The deposition method of claim 16, wherein the second positive voltage is +500 V or less.

19. The deposition method of claim 16, wherein the semiconductor substrate comprises silicon, and wherein pre-treatment process produces an oxygen-radicalized surface termination of the silicon of the semiconductor substrate.

20. The deposition method of claim 19, wherein the deposition process produces a silicon oxide film overlying the semiconductor substrate, the silicon oxide film having a thickness of or about 2.5 μm.
